(19) United States
(12) Patent Application Publication
(10) Pub. No.: US 2013/0223001 A1
(43) Pub. Date: Aug. 29, 2013

(54) PRINTED CIRCUIT BOARD AND MEMORY MODULE COMPRISING THE SAME

(71) Applicant: Samsung Electronics Co., Ltd., (US)

(72) Inventors: Hwang-bok Ryu, Asan-si (KR); Jun-young Ko, Cheonan-si (KR); Young-ja Kim, Asan-si (KR); Dae-young Jeong, Dong-gu (KR)

(73) Assignee: SAMSUNG ELECTRONICS CO., LTD., Suwon-si (KR)

(21) Appl. No.: 13/685,076

(22) Filed: Nov. 26, 2012

(30) Foreign Application Priority Data
Feb. 24, 2012 (KR) 10-2012-0019168

(51) Int. Cl. H05K 7/06; G06F 1/16

(52) U.S. Cl. CPC H05K 7/06; G06F 1/16
USPC 361/679.32; 361/774

(57) ABSTRACT

A printed circuit board (PCB) comprises an internal wiring layer, an insulating layer on the internal wiring layer, a via hole extending through the insulating layer, and an external wiring layer on the insulating layer. The internal wiring layer comprises at least one metal wiring layer. The via hole exposes the internal wiring layer. The external wiring layer is electrically connected to the internal wiring layer. The external wiring layer includes a mounting area on which a semiconductor chip is disposed and a non-mounting area on which a semiconductor chip is not disposed. A thickness of the mounting area is less than a thickness of the non-mounting area.

### CROSS-REFERENCE TO RELATED APPLICATIONS

This application claims the benefit of Korean Patent Application No. 10-2012-0019168, filed Feb. 24, 2012 in the Korean Intellectual Property Office, the disclosure of which is incorporated herein in its entirety by reference.

### BACKGROUND

The inventive concepts relate to a memory module, and more particularly, to a printed circuit board (PCB) for a memory module and a memory module including the PCB.

Memory modules are provided to increase memory capacity of computer devices. Memory modules may be broadly classified as either a single in-line memory module (SIMM) or a dual in-line memory module (DIMM). A SIMM has pins formed on only one surface of a PCB. In contrast, a DIMM has pins formed on two surfaces of a PCB. Although memory chips may be mounted on either one or two surfaces of a PCB, a SIMM generally has memory chips mounted on one surface of a PCB and a DIMM generally has memory chips mounted on two surfaces of a PCB due to the structural characteristics of the SIMM and the DIMM, respectively.

### SUMMARY

In accordance with embodiments of the inventive concepts, provided is a printed circuit board (PCB) and a memory module including the PCB, wherein, in the PCB, wiring pitches of areas where semiconductor chips are disposed are narrowly formed along bump pitches of the semiconductor chips and wiring pitches of remaining areas are broadly formed for a memory module on which the semiconductor chips are disposed using a flip-chip method.

According to an aspect of the inventive concepts, provided is a printed circuit board (PCB) comprising an internal wiring layer comprising at least one metal wiring layer; an insulating layer on the internal wiring layer, a via hole extending through the insulating layer, the via hole exposing the internal wiring layer; and an external wiring layer on the insulating layer and electrically connected to the internal wiring layer, wherein the external wiring layer includes a mounting area on which a semiconductor chip is disposed and a non-mounting area on which a semiconductor chip is not disposed, and wherein a thickness of the mounting area is less than a thickness of the non-mounting area.

In an embodiment, wiring of the mounting area is formed having a single layer, and wiring of the non-mounting area is formed having at least two metal layers.

In an embodiment, the insulating layer is formed on upper and lower surfaces of the internal wiring layer, wherein the via hole is formed in the insulating layer of the upper surface, wherein a plating layer is formed on a bottom and a wall of the via hole.

In an embodiment, the external wiring layer includes a portion of the plating layer at the mounting area, the portion of the plating layer extending from the via hole.

In an embodiment, the insulating layer is formed on each of an upper surface and a lower surface of the internal wiring layer, wherein the via hole is formed in each of the upper and lower insulating layers, and wherein the external wiring layer is formed on each of the upper and lower insulating layers.

In an embodiment, each of the upper and lower external wiring layers is divided into a mounting area on which a semiconductor chip is mounted and a non-mounting area on which a semiconductor chip is not mounted, and wherein a thickness of wiring of the upper and lower mounting areas is less than a thickness of wiring of the upper and lower non-mounting areas.

In an embodiment, the internal wiring layer comprises a central insulating layer and a metal layer on at least one of an upper surface or a lower surface of the central insulating layer.

In an embodiment, the internal wiring layer is formed of copper, wherein the insulating layer is formed of a pre-impregnated material (prepreg), and wherein the external wiring layer of the mounting area is formed of copper and the external wiring layer of the non-mounting area is formed of copper and nickel.

According to another aspect of the inventive concept, provided is a memory module comprising: a printed circuit board (PCB), comprising: an internal wiring layer comprising at least one metal wiring layer; an insulating layer that is formed on the internal wiring layer; a via hole extending through the insulating layer, the via hole exposing the internal wiring layer; and an external wiring layer that is formed on the insulating layer and that is electrically connected to the internal wiring layer, wherein the external wiring layer includes a mounting area on which a semiconductor chip is disposed and a non-mounting area on which a semiconductor chip is not disposed, and wherein a thickness of the mounting area is less than a thickness of the non-mounting area. The memory module further comprises at least one semiconductor chip that is mounted on the mounting area of the PCB by a flip-chip method.

In an embodiment, wiring of the mounting area is formed having a single layer and formed having a fine pitch along a bump pitch of the semiconductor chip, and wiring of the non-mounting area is formed having at least two metal layers.

In an embodiment, the memory module further comprises at least one of a passive component and a buffer chip that are mounted at the non-mounting area.

In an embodiment, the memory module further comprises a plating layer on a bottom and a wall of the via hole, wherein the plating layer is extended on the external wiring layer of the mounting area from the via hole.

In an embodiment, the insulating layer is formed on each of an upper surface and a lower surface of the internal wiring layer, wherein the external wiring layer is formed on each of the upper and lower insulating layers, wherein the semiconductor chip is mounted on each of the external wiring layers on the upper and lower insulating layers.

In an embodiment, the internal wiring layer comprises a central insulating layer and a metal layer on at least one of an upper surface or a lower surface of the central insulating layer.

In an embodiment, the memory module may be a small outline dual in-line memory module (SODIMM).

According to another aspect of the inventive concept, provided is a printed circuit board (PCB), comprising: a first region at which a semiconductor chip is disposed, the first region including a wiring layer having a first thickness; a second region including elements other than the semiconductor chip, the second region including a wiring layer having a second thickness; and a wiring layer having a first portion at the first region and a second portion at the second region, wherein the first portion of the wiring layer at the first region has a thickness that is less than a thickness of the second portion of the wiring layer at the second region.

In an embodiment, the wiring is formed of a patterned Cu foil.

In an embodiment, the PCB further comprises a body unit, the wiring layer positioned on the body unit.

In an embodiment, the PCB further comprises an internal wiring layer formed in the body unit, the internal wiring layer comprising at least one metal wiring layer.

In an embodiment, the PCB further comprises a via hole extending through the body unit, the via hole exposing the internal wiring layer, wherein the wiring layer is electrically connected to the internal wiring layer at the via hole.

### BRIEF DESCRIPTION OF THE DRAWINGS

Exemplary embodiments of the inventive concept will be more clearly understood from the following detailed description taken in conjunction with the accompanying drawings in which:

FIG. 1 is a plan view of a memory module according to an embodiment of the inventive concepts;

FIG. 2 is a plan view of a printed circuit board (PCB) of the memory module of FIG. 1;

FIG. 3 is a plan view illustrating a magnified wiring portion on which a semiconductor chip is mounted on the PCB of FIG. 2;

FIGS. 4A through 4F are cross-sectional views illustrating a process of manufacturing a PCB according to an embodiment of the inventive concepts;

FIG. 5 is a cross-sectional view illustrating a degree of patterning according to a thickness in a subtractive patterning method performed on a Cu foil;

FIG. 6 is a plan view of a memory module according to another embodiment of the inventive concept;

FIG. 7 is a plan view of a memory module according to another embodiment of the inventive concepts;

FIG. 8 is a cross-sectional view of a PCB of the memory module of FIG. 7;

FIG. 9 is a perspective view illustrating a structure of memory modules according to an embodiment of the inventive concept connected to a memory controller; and

FIG. 10 is a block diagram schematically illustrating an electronic system including a memory module according to an embodiment of the inventive concept.

### DETAILED DESCRIPTION OF THE EMBODIMENTS

The inventive concept will now be described more fully with reference to the accompanying drawings, in which exemplary embodiments of the inventive concept are shown. The inventive concept may, however, be embodied in many different forms and should not be construed as being limited to the embodiments set forth herein; rather, these embodiments are provided so that this disclosure will be thorough and complete, and will fully convey the scope of the inventive concept to those of ordinary skill in the art

It will be understood that when an element is referred to as being connected to another element, the element can be directly connected to the other element or intervening elements may be present therebetween. Similarly, when an element is referred to as being on another element, it can be directly on the other element or intervening elements may be present therebetween. Also, a structure or a size of each element in the drawings is exaggerated for clarity and convenience of explanation, and parts unrelated to the description will be omitted. Like reference numbers represent like elements throughout the drawings. Meanwhile, the terms in the following description are used for explaining the inventive concept, and do not limit the scope of the claims.

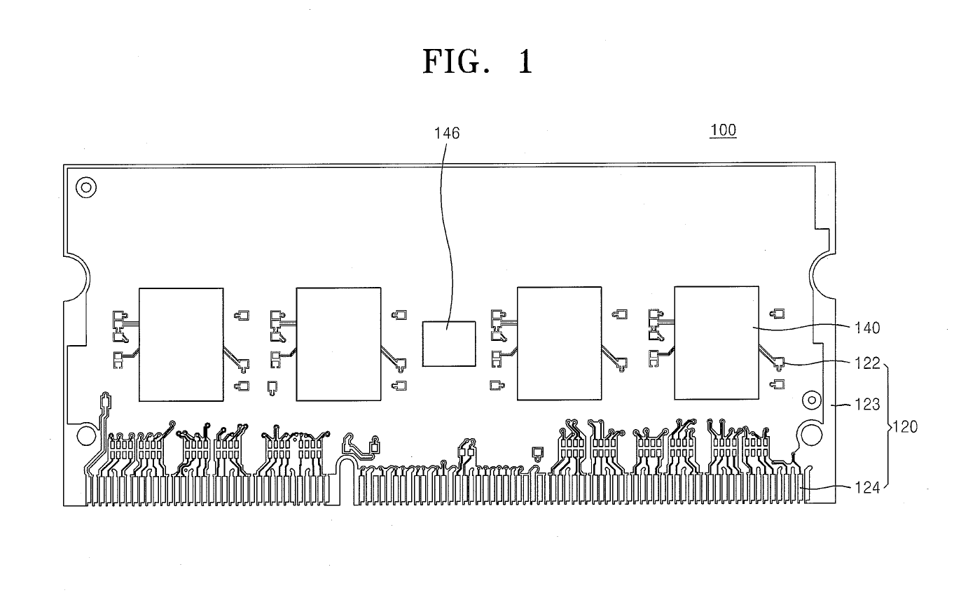

FIG. 1 is a plan view illustrating a memory module 100 according to an embodiment of the inventive concept. In an embodiment, the memory module 100 includes a printed circuit board (PCB) 120 and a semiconductor chip 140.

The PCB 120 can be manufactured by laminating a copper (Cu) foil on a plate comprising phenol or epoxy glass (or FR-4) resin compressed to have an even thickness. Circuit wiring can be formed on the plate by patterning the Cu foil, and thus an electronic component such as a semiconductor chip may be mounted on the plate via one or more bumps.

The PCB 120 may be classified as a single layer PCB having wiring only on one surface or as a double layer PCB having wiring on two surfaces. Also, the Cu foil may be formed in three or more layers using an insulator such as a pre-impregnated material, or prepreg. According to the number of layers of the Cu foil, three or more wiring layers may be formed on the PCB 120.

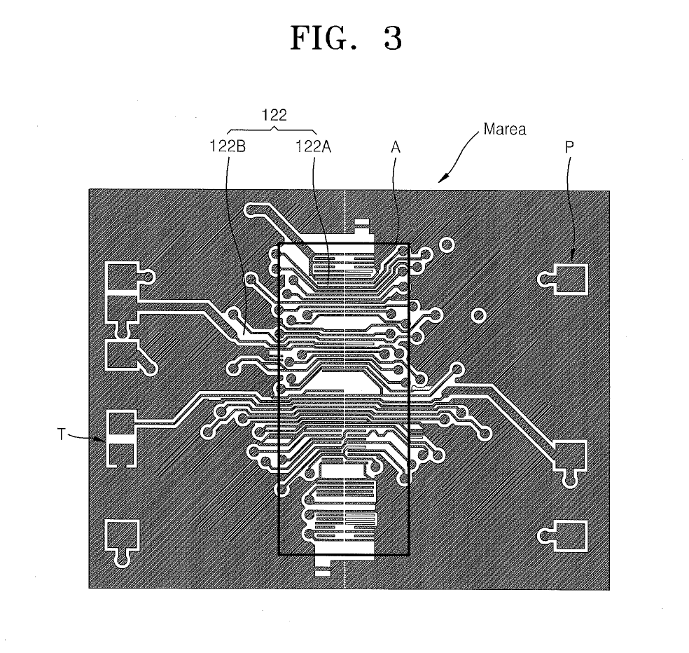

An external wiring layer 122 can be formed on at least one surface of the PCB 120 according to the current embodiment. The wiring layer 122 may be divided into an area (hereinafter, refers to as “a mounting area”) on which the semiconductor chip 140 is mounted via one or more bumps, and a remaining area. Also, a thickness and an interval of wiring formed on a mounting area may be smaller than a thickness and an interval of wiring formed on a non-mounting area. Differences between the mounting area and the non-mounting area, the thicknesses and the intervals of the wiring thereof, and the like will be described in detail in description of FIGS. 3 through 5.

Reasons why the external wiring layer 122 is divided into the mounting area and the non-mounting area and formed to have different thicknesses and intervals are described as follows.

In the current embodiment, semiconductor chips may be mounted on at least one surface of the PCB 120 using a flip-chip method. As recent technological advances have resulted in a reduction in size of semiconductor chips, and an increase in a number of bumps for connecting semiconductor chips and a PCB, a bump pitch has been reduced. Also, wiring formed on an area where a semiconductor chip is mounted is required having a relatively fine pitch to correspond to a reduced bump pitch. Meanwhile, a terminal pad for applying signal or power may be formed on a non-mounting area. Also, a passive component or a buffer chip may be mounted on a non-mounting area. Wiring of a non-mounting area is not required to be formed at a relatively fine pitch. That is, in order to maintain a rigidity of the PCB 120, wiring of the non-mounting area may be formed to be relatively thick in a wide pitch pattern.

Thus, the PCB 120 of the current embodiment may have a relatively fine bump pitch for a semiconductor chip to be mounted thereon and maintain the same rigidity as a conventional PCB by reducing the thickness and the interval of the wiring of the mounting area on which a semiconductor chip 140 is mounted, and increasing the thickness and the interval of the wiring of the non-mounting area, which can the remaining area not occupied by the mounting area. Also, an efficient and reliable memory module, for example, a dual-inline memory module (DIMM), may be provided that includes the PCB 120.

The semiconductor chip 140 mounted on the PCB 120 may be a memory chip or a logic chip. In embodiments where the semiconductor chip 140 is includes a memory chip, the semiconductor chip 140 may be a DRAM, SRAM, flash memory, EEPROM, PRAM, MRAM, or RRAM. In the current embodiment, the semiconductor chip 140 may be a DRAM.

The semiconductor chip 140 may be mounted only on one surface of the PCB 120 as described above or, alternatively, may be mounted on two surfaces of the PCB 120. Also, although four (4) semiconductor chips are shown to be mounted in FIG. 1, in other embodiments, the number of semiconductor chips is not limited to 4. For example, eight (8) or sixteen (16) semiconductor chips may be mounted on the PCB 120.

Although the semiconductor chip 140 in the drawings is shown as having a shape of a rectangle, the semiconductor chip 140 may be mounted on the PCB 120 in a packaged form to be sealed with a sealing material rather than being mounted on the PCB 120 in a bare chip form. Here, a buffer chip 146 can be disposed between a DRAM and a memory controller and serve to relay a data transfer. For example, the buffer chip 146 may be an advanced memory buffer (AMB). An AMB connected to a DRAM chip 140 installed at the memory module 100 may store data transferred from a memory controller in the DRAM and may read data from the DRAM and transfer the data to the memory controller. Also, an AMB may transfer a data storage or read request of a memory controller to an AMB of a memory module installed in a next slot. Therefore, the memory module 100 may have a high transfer bandwidth and a high capacity by including the buffer chip 146. The memory module 100 of the current embodiment includes an optional buffer chip 146. In other embodiments, the buffer chip 146 is omitted.

Here, the PCB 120 can include a plurality of terminal pins 124. When terminal pins 124 of a PCB 120 are formed only on one surface of the PCB 120, the memory module thereof is a SIMM. In other embodiments, terminal pins of a PCB are formed on two surfaces of the PCB, the memory module thereof is a DIMM. The PCB 120 inserted in a socket of a main board in a laptop, a smart phone, or the like may be electrically connected with the main board via the terminal pins 124. The memory module 100 of the current embodiment may be a DIMM, particularly a small outline DIMM (SODIMM) that may be applied in a mobile device such as a smart phone, a laptop, a netbook, a smart pad, or the like.

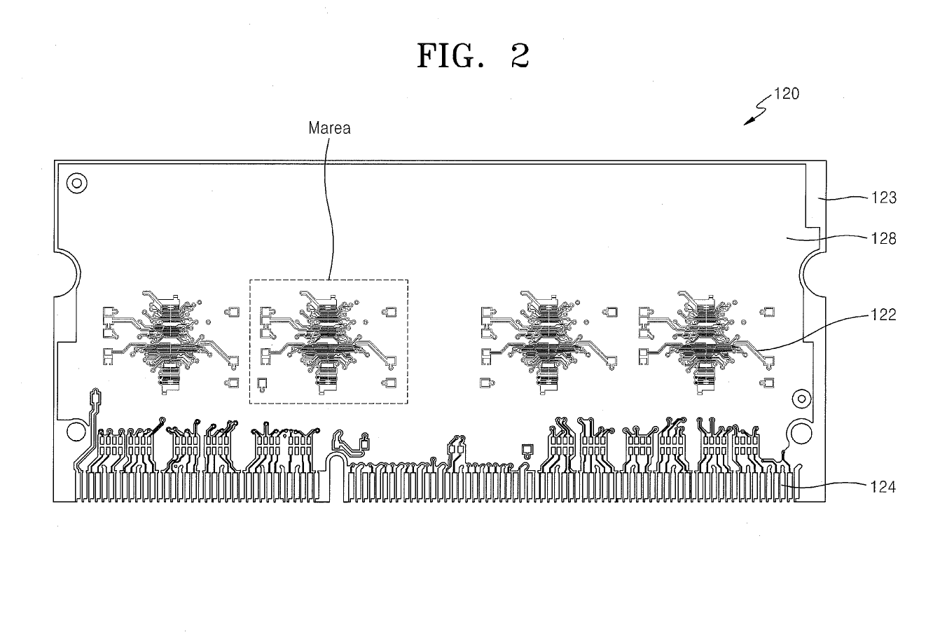

FIG. 2 is a plan view of the PCB 120 of the memory module 100 of FIG. 1.

Referring to FIG. 2, the PCB 120 according to an embodiment may include the external wiring layer 122, the terminal pins 124, a body unit 123, and an internal wiring layer (not shown).

The external wiring layer 122 may be formed of a Cu foil. However, a material of the external wiring layer 122 is not limited to Cu foil. For example, the external wiring layer 122 may be formed of a metal layer of aluminum (Al), nickel (Ni), or the like other than Cu. Also, the external wiring layer 122 may be formed in Ni/Cu, Al/Ni, or TiW/Ni multi-layers of metal wiring instead of in a single layer.

The external wiring layer 122 may be broadly divided into a mounting area and a non-mounting area. The mounting area, on which semiconductor chips are mounted via bumps, may have wiring thereon having a reduced thickness and interval. That is, the thickness and interval of the wiring of the mounting area are formed to correspond with pitches of the bumps formed on the semiconductor chips mounted on the mounting area.

The non-mounting area includes an area other than the mounting area and is an area on which semiconductor chips are not mounted. The wiring of the non-mounting area may be formed to be relatively thick in a wider interval compared to the wiring of the mounting area. Meanwhile, passive components (not shown) or buffer chips (not shown) may be mounted on the non-mounting area. Also, terminal pads may be formed on the non-mounting area for applying signal or power, and via holes that connect the external wiring layer 122 and the internal wiring layer may be disposed.

The terminal pins 124 are electrically connected to semiconductor chips mounted on the PCB 120 through the external wiring layer 122 and the internal wiring layer. As described above, the semiconductor chips may be electrically connected to electronic components disposed on a main board by electrically connecting the PCB 120 to the main board. In the current embodiment, the terminal pins 124 may be formed on two surfaces of the PCB 120, and thereby the PCB 120 of the current embodiment may be a PCB for a DIMM or a PCB for a SODIMM, which is particularly applied to mobile devices.

The body unit 123, also referred to as an insulating layer, may be formed of phenol or epoxy resin. The body unit 123 may be divided into an upper body unit and a lower body unit. Also, if the internal wiring layer is formed as multi-layers, prepreg may be used to form the body unit 123. An insulating film 128 can be formed on the body unit 123.

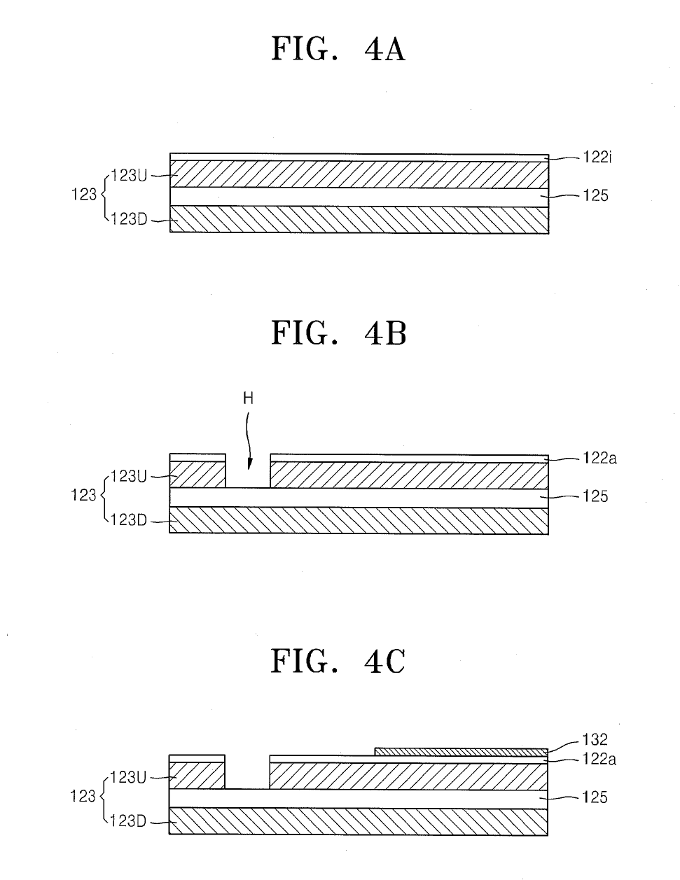

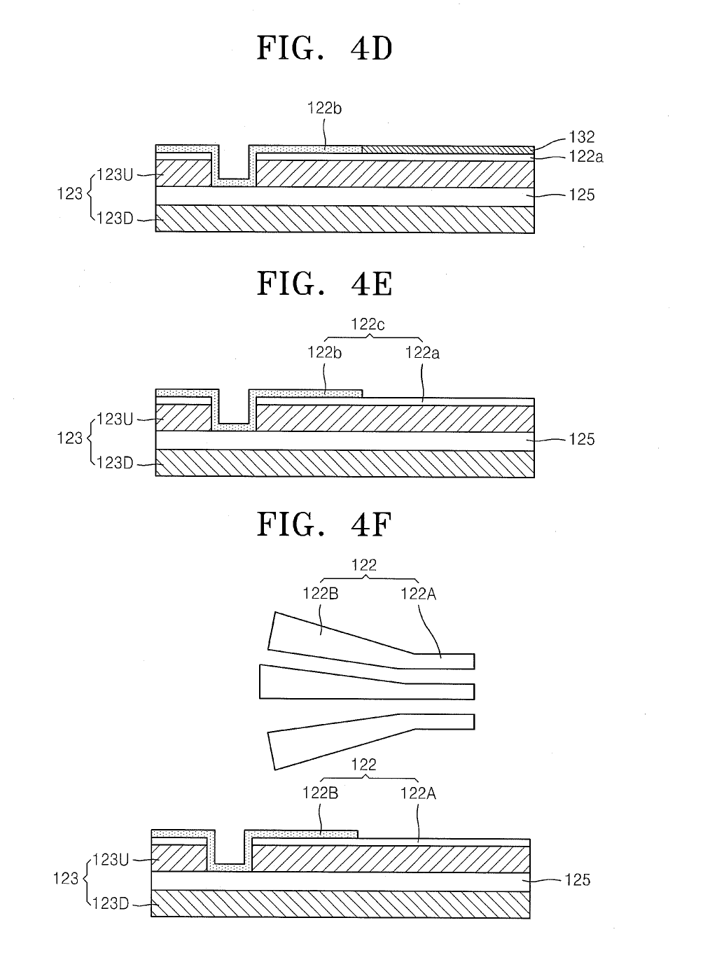

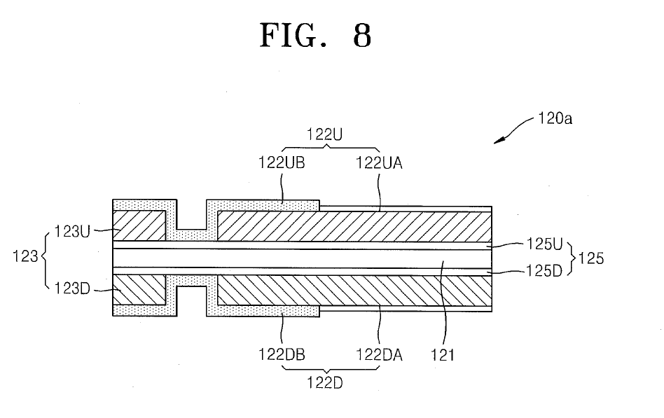

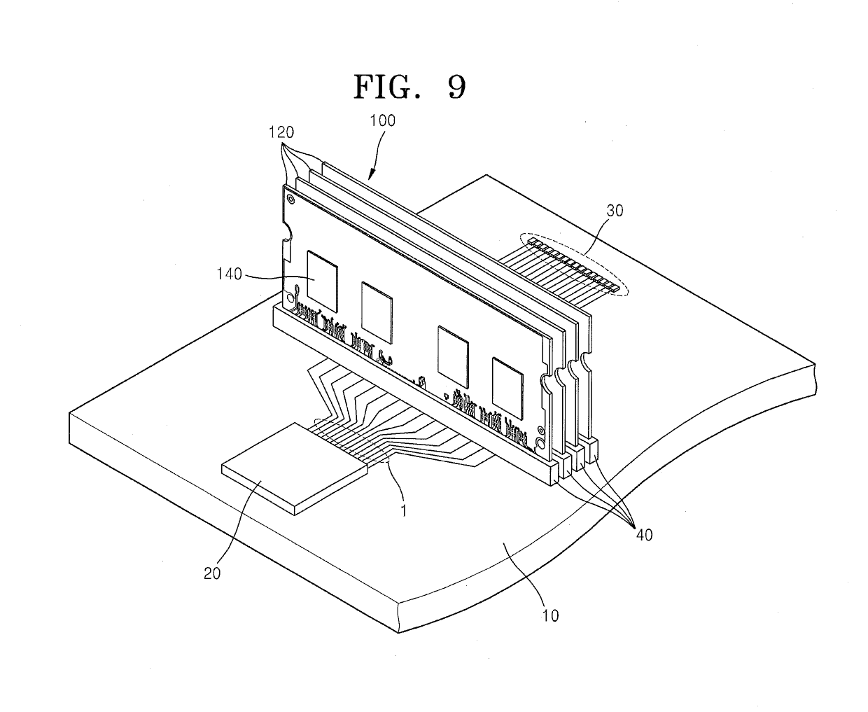

The internal wiring layer (not shown) is a wiring layer formed inside the body unit 123 and may be formed of a metal layer, such as Cu. Such internal wiring layer may be formed in a single layer or multi-layers. The internal wiring layer will be described in detail in description of FIGS. 4A through 4F and FIG. 8.

FIG. 3 is a plan view illustrating a magnified wiring portion on which a semiconductor chip is mounted (Marea) on the PCB 120 of FIG. 2.

Referring to FIG. 3, the external wiring layer 122 may be divided into a fine wiring 122A formed inside a mounting area A and a general wiring 122B formed outside the mounting area A, as illustrated in the drawing. Here, a semiconductor chip may be mounted using a flip-chip method.

Here, a reference number T may represent portions where terminal pads for applying signal or power may be formed, and P may represent portions where passive components are mounted. Various wiring other than wiring related to terminal pads or passive components may be formed on the non-mounting area of the PCB 120.

FIGS. 4A through 4F are cross-sectional views illustrating a process of manufacturing a PCB 120 according to an embodiment of the inventive concepts. In describing the process, reference is made to the PCB 120 of FIG. 2.

Referring to FIG. 4A, a Cu foil 122i is attached on a body unit 123, in which an internal wiring layer 125 is formed. A thickness of the attached Cu foil 122i may be several to several tens of μm.

The body unit 123 may be divided into an upper body unit 123U and a lower body unit 123D. The internal wiring layer 125 is between the upper body unit 123U and the lower body unit 123D. The body unit 123 may be formed of phenol or epoxy resin. Also, the body unit 123 may be formed of prepreg.

The internal wiring layer 125 may be formed of a metal such as Cu, Al, or Ni. The internal wiring layer 125 may be formed in a single layer or multiple layers.

Referring to FIG. 4B, a via hole H is formed that extends through the Cu foil 122i and the upper body unit 123U and exposes an upper surface of the internal wiring layer 125. The via hole H may be formed by chemical etching or by laser drilling. Generally, a laser drilling method is used. Alternatively, a chemical etching method may be used, for example, in cases where the Cu foil 122a is relatively thick. For the laser drilling method, a CO₂ laser or a YAG laser may be used. In an embodiment, a CO₂ laser is used, for example, to form a hole penetrating a substrate with high power. In another embodiment, a YAG laser is used, for example, to puncture a portion of a substrate with low power.

The via hole H is disposed to form an electrical path connecting the external wiring layer 122 (see FIG. 4F) to the internal layer 125.

Referring to FIG. 4C, a protective film 132 is formed on a predetermined region of the Cu foil 122a, preferably after forming the via hole H. The region where the protective film 132 is formed may be the mounting area, on which a semiconductor chip is mounted. The protective film 132 may be formed of a dry film resist (DFR).

Referring to FIG. 4D, a plating layer 122b is formed on an upper surface of a region of the Cu foil 122a other than the region where the protective film 132 is formed. The plating layer 122b may also be formed on a wall and a bottom surface of the via hole H.

The plating layer 122b may be formed by non-electrolytic plating and electrolytic plating. That is, non-electrolytic plating is first performed to form a non-electrolytic plating layer, and then electrolyte plating may be performed with the non-electrolytic plating layer as a seed metal to form the plating layer 122b. The plating layer 122b may be formed on the wall surface of the via hole H by non-electrolytic plating.

The Cu foil 122a on the upper surface of the PCB 120 may be electrically connected with the internal wiring layer 125 through the plating layer 122b. The plating layer 122b may be formed of Cu using the same material as that of the Cu foil 122a. Occasionally, the plating layer 122b may be formed of a metal other than Cu. For example, the plating layer 122b may be formed of Ni, Ni/Cu, or the like.

Referring to FIG. 4E, after forming the plating layer 122b, the protective film 132 is removed. The protective layer 132 may be removed by aching and/or stripping. As the protective film 132 is removed, a metal layer 122c having two different thicknesses may be formed on the PCB 120. That is, the metal layer 122c may be divided into a region only having the Cu foil 122a exposed by removal of the protective layer 132 and a region additionally having the plating layer 122b on the Cu foil 122a. The region only having the Cu foil 122a may correspond to the mounting area, and the region additionally having the plating layer 122b may correspond to the non-mounting area. For example, the region only having the Cu foil 122a may have a thickness that is 30% or more thinner than the region additionally having the plating layer 122b.

Referring to FIG. 4F, the external wiring layer 122 is formed by performing a patterning process on the metal layer 122c, which is divided into the two regions. In FIG. 4F, a cross-sectional structure and a plane structure of the external wiring layer 122 are both illustrated. Pattern formation on both regions of the metal layer 122c may be performed at the same time or separately. If a general wide pattern is to be formed over an entire surface, the patterning process may be performed on both of the regions at the same time. However, if a wide pattern is to be formed on one part, and a relatively fine pattern is to be formed on the other part, separate patterning processes may be performed on the corresponding regions.

Particularly, a method of patterning a metal layer may be generally divided into a subtractive type and an additive type. A subtractive type method is a method of removing a metal layer through etching and is normally used to form a large pattern. An additive type method is a method of forming an additional metal pattern through plating on a metal layer and is normally used to form a relatively fine pattern. A subtractive type method typically costs less than an additive type method. Accordingly, a subtractive type method is typically used to manufacture a PCB for a module, which has a relatively large pattern, and an additive type method is typically used to manufacture a component PCB or a high-priced PCB for a large scale integrated circuit (LSI), which has a relatively small pattern.

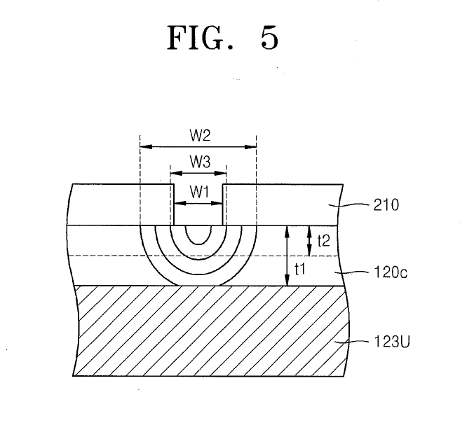

In the current embodiment, a subtractive type method of patterning may be used to form wiring of a PCB. A subtractive type method is used to form a relatively large wiring pattern. However, as described above, an area where a semiconductor chip is to be mounted needs to have a relatively fine pattern. If a thickness of a metal layer to be patterned is relatively thick and the thick metal layer is formed, by a subtractive type patterning, a relatively fine pattern may not be formed. However, if a thickness of a metal layer is relatively thin, a relatively fine pattern may be formed by a subtractive type patterning. A patterning process in accordance with embodiments of the inventive concepts will be described in detail in description of FIG. 5.

A PCB and a method of manufacturing the PCB in accordance with an embodiment comprises the forming of a thin wiring layer on a mounting area requiring a relatively fine pitch and forming a thick wiring layer on a non-mounting area requiring a relatively large pitch. To achieve this, a low-priced subtractive type patterning may be applied to form a wiring pattern having a relatively fine pitch on the mounting area and a wiring pattern having a relatively large pitch on the non-mounting area.

FIG. 5 is a cross-sectional view illustrating a degree of patterning according to a thickness in a subtractive patterning method performed on a Cu foil.

Referring to FIG. 5, a photoresist (PR) pattern 210 is first formed on a metal layer 120c in order to pattern the metal layer 120c with a subtractive patterning method. Then, an exposed portion of the metal layer 120c is etched, corroded, or otherwise modified using the PR pattern 210 as a mask. In the etching or corroding process, if the metal layer 120c is relatively thick, the etching process may take a relatively long time to completely etch and remove the metal layer 120c up to a bottom surface even if an interval of the PR pattern 210 is formed narrowly. Accordingly, an interval of a pattern of the metal layer 120c is larger than the interval of the PR pattern 210.

Particularly, if the metal layer 120c has a first thickness t1, a space having a second width W2 may be formed on the metal layer 120c through the PR pattern 210 where a space having a first width W1 is formed. However, if the metal layer 120c has a second thickness t2, a space having a third width W3 may be formed on the metal layer 120c using the PR pattern 120 where the space having the first width W1 is formed. Accordingly, a direct relationship is established between the thickness of the metal layer 120c and the width of the space formed on metal layer 120c.

A PR pattern is used in the current embodiment, but the current embodiment is not limited thereto, and a DFR pattern may be used for patterning a metal layer.

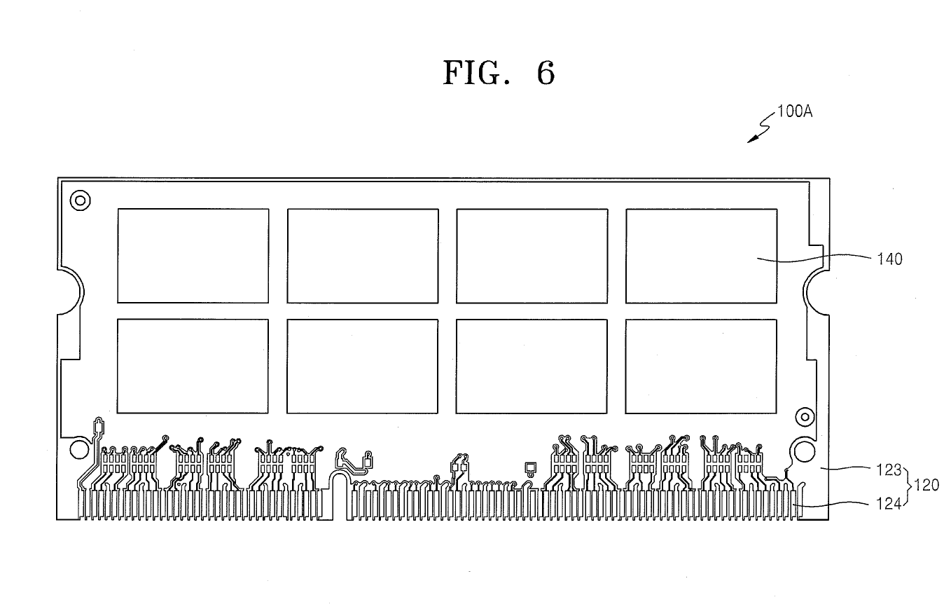

FIG. 6 is a plan view of a memory module according to another embodiment of the inventive concept. For convenience of explanation, the description for FIGS. 1 through 4F mentioned above will be briefly described or omitted.

Referring to FIG. 6, a memory module 100A according to the current embodiment is similar to the memory module 100 of FIG. 1, except for a greater number of semiconductor chips mounted on the PCB 120. That is, unlike the memory module 100 of FIG. 1, which has 4 semiconductor chips, 8 semiconductor chips 140 may be mounted on the PCB 120 according to the current embodiment.

Meanwhile, although the buffer chip 146 is disposed on the PCB 120 of the memory module 100 of FIG. 1, the buffer chip 146 is not disposed on the PCB 120 shown in FIG. 6. Nevertheless, in another embodiment, a buffer chip may be disposed on the PCB 120 of the memory module 100A of the current embodiment. The memory module 100A of the current embodiment may be a DIMM, particularly, a SODIMM. Accordingly, terminal pins may be formed on two surfaces of the PCB 120.

For the PCB 120 of the memory module 100A of the current embodiment, external wiring layers may also be divided into the mounting area and the non-mounting area. Also, the wiring of the mounting area may have a relatively thin thickness and a pattern having a relatively fine pitch while the wiring of the non-mounting area may have a relatively thick thickness and a pattern having a relatively large pitch.

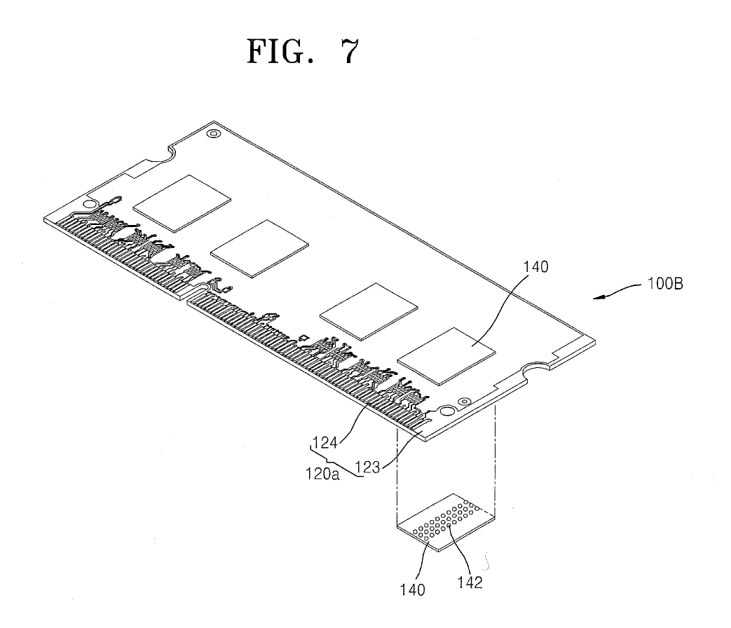

FIG. 7 is a plan view of a memory module according to another embodiment of the inventive concepts. For convenience of explanation, the description for FIGS. 1 through 4F mentioned above will be briefly described or details on elements of FIGS. 1 through 4F will not be repeated for brevity.

Referring to FIG. 7, a memory module 100B according to the current embodiment is similar to the memory module of FIG. 1, except for a structure of semiconductor chips mounted on a PCB 120a. That is, unlike the memory module 100 of FIG. 1, which has 4 semiconductor chips on one surface of the PCB 120, 4 semiconductor chips 140 may be mounted on each of two surfaces of the PCB 120a of the current embodiment.

Unlike FIG. 1, in which a buffer chip 146 is disposed on a PCB 120 of a memory module 100, a buffer chip is not disposed on the PCB 120a of the memory module 100B as shown in an embodiment of FIG. 7. In other embodiments, however, a buffer chip may be disposed on the PCB 120a of the memory module 100B. The memory module 100B of the current embodiment may also be a DIMM, particularly, a SODIMM. For reference, when a memory module is implemented as a SODIMM, a structure of the memory module 100B of the current embodiment, which has semiconductor chips on two surfaces of the PCB 120a, may be a common structure due to characteristics of a structure of a SODIMM.

A plurality of bumps 142 may be disposed on a semiconductor chip in order to mount the semiconductor chip on a PCB of a memory module in the current embodiment by a flip-chip method.

For the memory module 100B of the current embodiment, 4 semiconductor chips are mounted on each of two surfaces of the PCB 120a. However, the number of semiconductor chips is not limited to 4. For example, 8 semiconductor chips may be mounted on each of two surfaces of a PCB.

For the memory module 100B of the current embodiment, external wiring layer formed on each of two surfaces of the PCB 120a may be divided into two areas, that is, a mounting area and a non-mounting area. Also, wiring at each mounting area may have a relatively thin thickness and include a pattern having a relatively fine pitch, and wiring of each non-mounting area may have a relatively thick thickness and include a pattern having a relatively large pitch. Hereinafter, a structure of the PCB 120a, which is used for the memory module 100B of the current embodiment, is described in detail in description of FIG. 8.

FIG. 8 is a cross-sectional view illustrating the PCB 120a of the memory module 100B of FIG. 7.

Referring to FIG. 8, the PCB 120a used for the memory module 100B of the current embodiment may include a central insulator 121, the internal wiring layer 125, the body unit 123, and the external wiring layer 122. The internal wiring layer 125 of the current embodiment may be composed of 2 wiring layers, unlike the internal wiring layer 125 of the PCB 120 of FIG. 4F. That is, the internal wiring layer 125 may be divided into an upper internal wiring layer 125U and a lower internal wiring layer 125D. Here, the central insulator 121 may be formed of epoxy glass resin.

The body unit 123 may also be divided into the upper body unit 123U and the lower body unit 123D. As shown in the drawing, the upper body unit 123U is formed on the upper internal wiring layer 125U, and the lower body unit 123D is formed under the lower internal wiring layer 125D. The upper body unit 123U and the lower body unit 123D may be formed of prepreg or the like.

The external wiring layer 122 may be divided into an upper external wiring layer 122U and a lower external wiring layer 122D. Each of the upper external wiring layer 122U and the lower external wiring layer 122D may be divided into a mounting area 122UA or 122DA and a non-mounting area 122UB or 122DB. As shown in the drawing, wiring of the mounting area 122UA or 122DA is formed to have a relatively thin thickness and a pattern having a relatively fine pitch, and wiring of the non-mounting area 122UB or 122DB is formed to have a relatively thick thickness and a pattern having a relatively large pitch.

For reference, a PCB including 4 basic layers of Cu foil is formed by first attaching a Cu foil on two surfaces of epoxy glass resin, depositing prepreg insulators or the like on the Cu foil, and attaching a Cu foil on surfaces of the prepreg insulators in order to form the PCB 120a. A PCB having a structure of FIG. 8 may be formed by performing processes of FIGS. 4B through 4F on two surfaces of the PCB including 4 layers of a Cu foil.

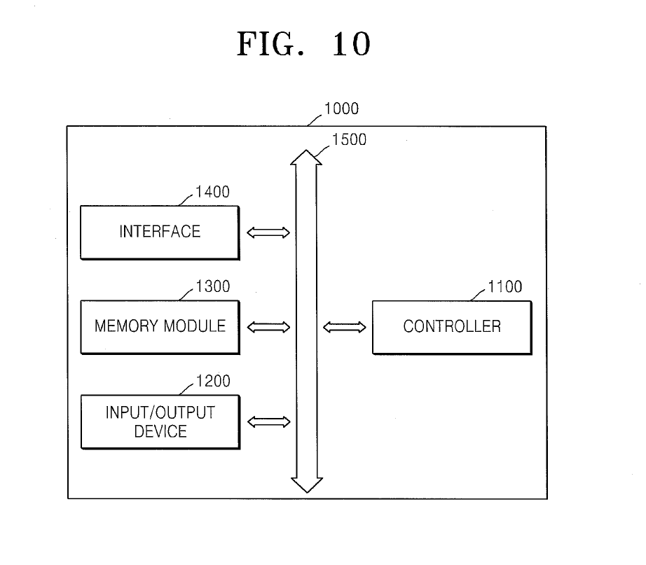

FIG. 9 is a perspective view illustrating a structure of memory modules according to an embodiment of the inventive concept connected to a memory controller.

Referring to FIG. 9, a plurality of connective sockets 40 may be electrically interconnected with a memory controller 20 mounted on a main board 10 via a bus 1. As many memory modules 100, 100A, or 100B having a layout structure that is the same as that of FIG. 1, 6, or 7 may be inserted in the connective sockets 40 as necessary. Here, a reference number 30 may represent termination resistances for impedance matching.

In a connection structure as shown in the drawing, a plurality of the memory modules 100, 100A, or 100B are each inserted in a corresponding connective socket 40, and data may be stored in semiconductor chips 140 or the data stored in the semiconductor chips 140 may be read in response to a memory controller 20.

FIG. 10 is a block diagram schematically illustrating an electronic system 1000 including a memory module 1300 according to an embodiment of the inventive concepts.

In addition to the memory module 1300, the electronic system 1000 may include a controller 1100, an in/output device 1200, and an interface 1400. The electronic system 1000 may be a mobile system or a system that sends or receives information. The mobile system may be a PDA, a portable computer, a web table, a wireless phone, a mobile phone, a digital music player, or a memory card.

The controller 1100 performs a program and serves to control the electronic system 1000. The controller 1100 may be, for example, a microprocessor, a digital signal processor, a microcontroller, or a device similar thereto. The in/output device 1200 may be used to input or output data of the electronic system 1000.

The electronic system 1000 may exchange data with an external device, for example, a personal computer or a network, by being connected to the external device using the in/output device 1200. The in/output device 1200 may be, for example, a keypad, a keyboard, or a display device. The memory module 1300 may store codes and/or data for operation of the controller 110 and/or may store data processed in the controller 1100. The memory module 1300 may include a memory module according to any one embodiment of the inventive concept. The interface 1400 may be a pathway for data transfer between the electronic system 1000 and other external devices. The controller 1100, the in/output device 1200, the memory module 1300, and the interface 1400 may communicate with each other via a bus 1500.

In other examples, the electronic system 1000 may be used in a mobile phone, an MP3 player, a navigator, a portable multimedia player (PMP), a solid state disk (SSD), or other electronic devices such as household appliances.

While the inventive concept has been particularly shown and described with reference to exemplary embodiments thereof, it will be understood that various changes in form and details may be made therein without departing from the spirit and scope of the following claims.

What is claimed is:

1. A printed circuit board (PCB), comprising:
an internal wiring layer comprising at least one metal wiring layer;
an insulating layer on the internal wiring layer;
a via hole extending through the insulating layer, the via hole exposing the internal wiring layer; and
an external wiring layer on the insulating layer and electrically connected to the internal wiring layer, wherein the external wiring layer includes a mounting area on which a semiconductor chip is disposed and a non-mounting area on which a semiconductor chip is not disposed, and wherein a thickness of the mounting area is less than a thickness of the non-mounting area.

2. The PCB of claim 1, wherein wiring of the mounting area is formed having a single layer, and wiring of the non-mounting area is formed having at least two metal layers.

3. The PCB of claim 1, wherein the insulating layer is formed on upper and lower surfaces of the internal wiring layer, wherein the via hole is formed in the insulating layer of the upper surface, wherein a plating layer is formed on a bottom and a wall of the via hole.

4. The PCB of claim 3, wherein the external wiring layer includes a portion of the plating layer at the mounting area, the portion of the plating layer extending from the via hole.

5. The PCB of claim 1, wherein the insulating layer is formed on each of an upper surface and a lower surface of the internal wiring layer, wherein the via hole is formed in each of the upper and lower insulating layers, and wherein the external wiring layer is formed on each of the upper and lower insulating layers.

6. The PCB of claim 5, wherein each of the upper and lower external wiring layers is divided into a mounting area on which a semiconductor chip is mounted and a non-mounting area on which a semiconductor chip is not mounted, and wherein a thickness of wiring of the upper and lower mounting areas is less than a thickness of wiring of the upper and lower non-mounting areas.

7. The PCB of claim 1, wherein the internal wiring layer comprises a central insulating layer and a metal layer on at least one of an upper surface or a lower surface of the central insulating layer.

8. The PCB of claim 1, wherein the internal wiring layer is formed of copper, wherein the insulating layer is formed of a pre-impregnated material (prepreg), and wherein the external wiring layer of the mounting area is formed of copper and the external wiring layer of the non-mounting area is formed of copper and nickel.

9. A memory module comprising:
a printed circuit board (PCB), comprising:
an internal wiring layer comprising at least one metal wiring layer;
an insulating layer that is formed on the internal wiring layer;
a via hole extending through the insulating layer, the via hole exposing the internal wiring layer; and
an external wiring layer that is formed on the insulating layer and that is electrically connected to the internal wiring layer, wherein the external wiring layer includes a mounting area on which a semiconductor chip is disposed and a non-mounting area on which a semiconductor chip is not disposed, and wherein a thickness of the mounting area is less than a thickness of the non-mounting area, the memory module further comprising:
at least one semiconductor chip that is mounted on the mounting area of the PCB by a flip-chip method.

10. The memory module of claim 9, wherein wiring of the mounting area is formed having a single layer, and formed having a fine pitch along a bump pitch of the semiconductor chip, and wherein wiring of the non-mounting area is formed having at least two metal layers.

11. The memory module of claim 10, further comprising at least one of a passive component and a buffer chip that are mounted at the non-mounting area.

12. The memory module of claim 9, further comprising a plating layer on a bottom and a wall of the via hole, wherein the plating layer is extended on the external wiring layer of the mounting area from the via hole.

13. The memory module of claim 9, wherein the insulating layer is formed on each of an upper surface and a lower surface of the internal wiring layer, wherein the external wiring layer is formed on each of the upper and lower insulating layers, wherein the semiconductor chip is mounted on each of the external wiring layers on the upper and lower insulating layers.

14. The memory module of claim 9, wherein the internal wiring layer comprises a central insulating layer and a metal layer on at least one of an upper surface or a lower surface of the central insulating layer.

15. The memory module of claim 9, wherein the memory module is a small outline dual in-line memory module (SODIM).

16. A printed circuit board (PCB), comprising:
a first region at which a semiconductor chip is disposed, the first region including a wiring layer having a first thickness;
a second region including elements other than the semiconductor chip, the second region including a wiring layer having a second thickness; and
a wiring layer having a first portion at the first region and a second portion at the second region, wherein the first portion of the wiring layer at the first region has a thickness that is less than a thickness of the second portion of the wiring layer at the second region.

17. The PCB of claim 16, wherein the wiring is formed of a patterned Cu foil.

18. The PCB of claim 16, further comprising a body unit, the wiring layer positioned on the body unit.

19. The PCB of claim 18, further comprising an internal wiring layer formed in the body unit, the internal wiring layer comprising at least one metal wiring layer.

20. The PCB of claim 19, further comprising a via hole extending through the body unit, the via hole exposing the internal wiring layer, wherein the wiring layer is electrically connected to the internal wiring layer at the via hole.
